(19) United States
(12) Patent Application Publication
(10) Pub. No.: US 2006/0286686 A1
(43) Pub. Date: Dec. 21, 2006

(54) Integrated light emitting diode displays using biofabrication

(75) Inventors: Kwok-Wai Lem, Randolph, NJ (US); Brian W. Walker, Marion, IA (US); Kalluri R. Sarma, Mesa, AZ (US); Peter A. Smith, South Amboy, NJ (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International, Inc.

(21) Appl. No.: 11/288,498

(22) Filed: Nov. 28, 2005

Related U.S. Application Data
(60) Provisional application No. 60/691,148, filed on Jun. 15, 2005.

(51) Int. Cl. H01L 21/00

(52) U.S. Cl. 438/1

(57) ABSTRACT

A method of manufacturing an integrated light emitting diode display is provided. In one exemplary embodiment, the method includes the step of biologically forming a pn junction over a substrate, the pn junction capable of emitting a light having a predetermined color upon the application of energy thereto. In another exemplary embodiment, a method of manufacturing a light emitting diode is provided. The method includes depositing a biological material over the substrate, the biological material having an affinity for a pn junction material, and exposing the deposited biological material to the first pn junction material to form a doped area of a pn junction. In still another exemplary embodiment, a light emitting diode is provided. The light emitting diode includes a substrate and a biologically formed pn junction disposed over the substrate, wherein light having a predetermined color is emitted upon application of energy to the pn junction.

### CROSS-REFERENCES TO RELATED APPLICATIONS

This application claims the benefit of U.S. Provisional Application No. 60/691,148, filed Jun. 15, 2005.

### FIELD OF THE INVENTION

The present invention generally relates to displays, and more particularly relates to displays having integrated light emitting diodes that are manufactured using biofabrication methods.

### BACKGROUND OF THE INVENTION

Light Emitting Diode (“LED”) displays are used for myriad purposes, such as for advertising, traffic control, sporting events, and other means of communication. Typical LED displays are made of numerous LEDs that each includes a semiconductor chip that is disposed in a bulb. Each chip is created from a wafer having various layers of crystalline or polycrystalline semiconductor materials deposited thereon, and a particular semiconductor material is used to provide a particular color to a LED. Typically, a wafer yields a number of LEDs that are capable of emitting the same color light when energy is supplied thereto. Because each LED contained in the display is a discrete element, a number of LEDs made from different wafers are needed to produce a multi-colored display. As a result, large amounts of materials may be needed. The individual LEDs are then assembled in a predetermined pattern, and coupled to a power supply to form the display.

To reduce the amount of materials used to create multi-colored displays, the use of an integrated LED (“ILED”) display has recently been proposed. An ILED is typically constructed on a single conventional semiconductor substrate, such as a silicon substrate, and similar to conventional LED displays, emits light when supplied with energy. However, the current process for manufacturing a multi-colored ILED involves very high temperatures (˜1000° C.), is relatively complex, and time-consuming to perform. As a result, the costs associated with ILED fabrication are relatively high. Additionally, because ILEDs are generally formed on semiconductor materials, light extraction is not as efficient as in conventional LED array displays. Attempts to increase light extraction have included constructing ILEDs over transparent substrates, such as, for example, glass or plastic substrates. However, the deposition of particular materials capable of emitting certain colors require a relatively high temperature, e.g. above about 1000° C., which does not allow use of the transparent substrate materials, as process temperatures for those materials are typically limited to around 300° C. or less.

Accordingly, it is desirable to have a process for manufacturing an ILED display that is relatively simple and capable of being performed at temperatures below 300° C. In addition, it is desirable for the process to produce high quality multi-color ILED displays. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

A method of manufacturing an integrated light emitting diode display is provided. In one exemplary embodiment, the method includes the step of biologically forming a pn junction over a substrate, the pn junction capable of emitting a light having a predetermined color upon the application of energy thereacross.

In another exemplary embodiment, a method of manufacturing a light emitting diode is provided. The method includes depositing a biological material over the substrate, the biological material having an affinity for a pn junction material, and exposing the deposited biological material to the pn junction material to form a first doped area of a pn junction capable of emitting a light having a predetermined color upon the application of energy thereacross.

In still another exemplary embodiment, a light emitting diode is provided. The light emitting diode includes a substrate and a biologically formed pn junction disposed over the substrate, wherein light having a predetermined color is emitted upon application of a energy across the pn junction.

### BRIEF DESCRIPTION OF THE DRAWINGS

The present invention will hereinafter be described in conjunction with the following drawing figures, wherein like numerals denote like elements, and

FIG. 1 is an exemplary integrated light emitting diode (“ILED”) display;

FIG. 2 is cross section view of an exemplary light emitting diode (“LED”) that may be implemented into the display of FIG. 1; and

FIG. 3 is a flow diagram of an exemplary method for manufacturing the ILED display depicted in FIG. 1.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

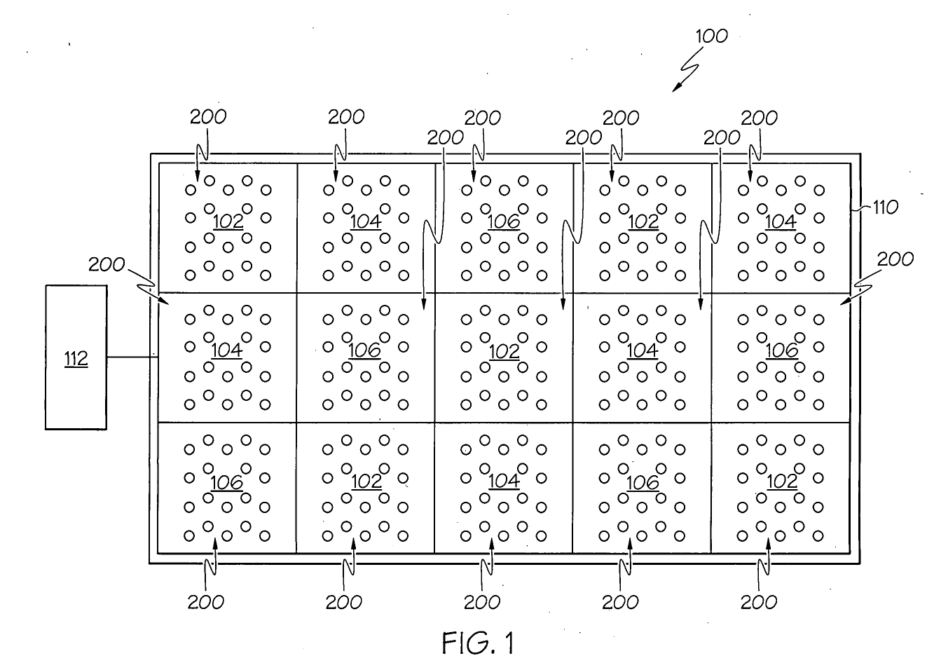

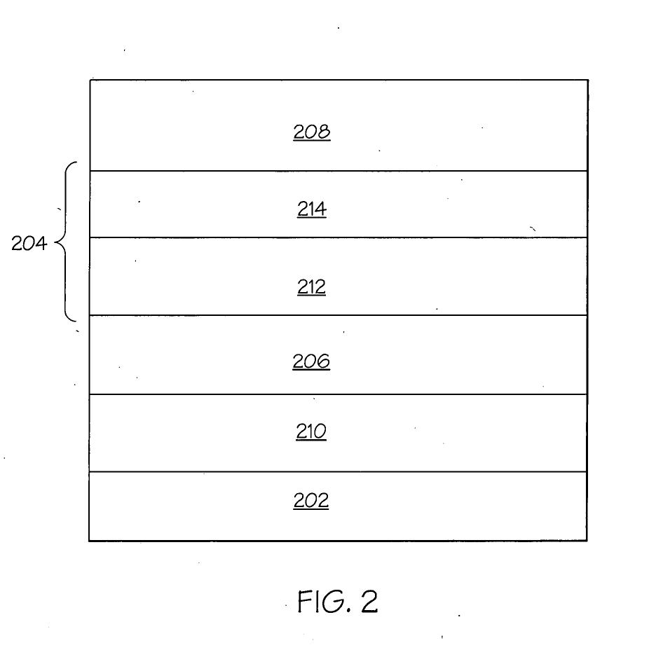

Turning now to FIG. 1, a portion of an exemplary multi-colored integrated light emitting diode (“ILED”) display 100 is depicted. The display 100 is preferably constructed on a single substrate 110 and includes a backplane electronics layer 201 (shown in FIG. 2) over which a plurality of diodes 200 are formed. The diodes 200 and the backplane electronics layer 201 are coupled to, and powered by, a display drive electronics 112 that supplies power thereto.

The substrate 110 is divided into a plurality of regions, each of which is further divided into at least three areas 102, 104, 106. Each of these areas 102, 104, 106 is capable of emitting light when energy is supplied thereto. Preferably, each area emits a light of a single color and the light emitted from one area is a different color than the light emitted from another area. For example, the first areas 102 are each configured to emit light of a first color, the second areas 104 are each configured to emit light of a second color, and the third areas 106 are configured to emit light of a third color.

To generate a color image on the display 100, color composites comprising three primary colors are preferably used. In one exemplary embodiment, additive color composites are used, and accordingly, the first, second and third colors used in the display 100 are red, green, and blue. In another exemplary embodiment, subtractive color composites are employed. In this regard, the first, second, and third colors are cyan, magenta, and yellow. Although the areas 102, 104, 106 are depicted in FIG. 1 as being disposed in a particular pattern, it will be appreciated that the areas 102, 104, 106 are most preferably disposed in a pattern that optimizes the ability of the additive or subtractive color composites to create different colors. Thus, the areas 102, 104, 106 may be disposed in any other suitable pattern.

Light is emitted from the plurality of areas 102, 104, 106 via the diodes 200. Although a plurality of diodes 200 is shown disposed in each of the areas 102, 104, 106, it will be appreciated that fewer or more may be alternatively incorporated therein. Turning to FIG. 2, one exemplary diode 200 is depicted. The diode 200 is formed over the backplane electronics layer 201 of a substrate 202 and is capable of emitting a light of a predetermined color. Each diode 200 includes a pn junction 204 and two conductors 206, 208 that are coupled thereto. In some embodiments, the diode 200 also includes a reflector 210 disposed between the substrate 202 and one of the conductors 206.

The substrate 202 may be any size and is configured to serve as a base upon which the plurality of diodes 200 are formed. Preferably, the substrate 202 is made of a relatively lightweight material and may be transparent or reflective. Suitable materials include, but are not limited to glass, plastic, steel, or aluminum. The backplane electronics layer 201 is configured to control the energy, for example, the voltage or current, that is supplied to the pn junction 204 and is thus preferably formed as a thin film transistor array for the ILED. The backplane electronics layer 201 may be constructed from any one of numerous semiconductor materials suitable for forming a thin film transistor, such as, for example, amorphous silicon, polysilicon, and organic semiconductor material.

The pn junction 204 is disposed over the backplane electronics layer 201 and includes a first doped area 212 that has been doped with a p-type dopant, and a second doped area 214 that has been doped with an n-type dopant, or vice versa. It will be appreciated that any one of numerous conventionally used semiconductor materials may be used; however, the first and second doped areas 212, 214 are preferably both made of the same material and the material has been doped by an n-type or p-type dopant. In one exemplary embodiment, the materials that form pn junction have dual properties for light emitting and other electromagnetic radiation detection/sensors functions, such as radar. In such case, suitable materials may include, but are not limited to ZnS and the like. Preferably, each pn junction 204 disposed in the first areas 102 of the display 100 include a first material, each pn junction 204 disposed in the second areas 104 of the display 100 include a second material, and each pn junction 204 disposed in the third areas 106 of the display 100 include a third material. Reasons for the use of the various materials will become clearer in the description further below.

At least a portion of each of the first and second doped areas 212, 214 is in electrical communication with the conductors 206, 208, respectively. The conductors 206, 208 are configured to receive energy from a non-illustrated power source, such as the display drive electronics 112 in FIG. 1 via the backplane electronics layer 201, and to provide a voltage or current across the pn junction 204. The conductors 206, 208 may have any one of numerous conventional configurations and may be made of any one of numerous conventionally used conductive materials. In one example shown in FIG. 2, the conductors 206, 208 are layers of conductive material that are each deposited or otherwise formed adjacent the first and second doped areas 212, 214 of the pn junction 204. Also shown in FIG. 2, the bottom conductor 206 is disposed between the pn junction 204 and the backplane electronics layer 201, while the top conductor 208 is disposed over the pn junction 204 and exposed. In another embodiment, the exposed top conductor 208 is preferably made of a substantially transparent material, such as, for example, indium-tin-oxide, or indium-zinc-oxide. Alternatively, any other suitable transparent conducting material for a top emission structure for extracting the emitted light from the top of an organic light emitting diode (OLED) device may be used. Examples of other suitable materials include, but are not limited to nanomaterials, carbon nanotubes, fullerenes, nanowires, organic semiconductor materials, conducting polymers and alike.

In some embodiments, the diode 200 includes a reflector 210. The reflector 210 is configured to efficiently reflect the light emitted from the pn junction 204 back towards the front electrode 208 and then to the viewer. In this regard, the reflector 210 may be formed from any one of numerous reflective materials. Examples of suitable materials include, but are not limited to aluminum, and chromium. In some top emission embodiments the bottom conductor 206 may also serve as a reflector, thereby eliminating the need for a separate reflector 210.

In one exemplary embodiment, the bottom conductor 206 is made of a transparent conducting material for light extraction from the bottom of the display through the substrate 202, and reflective material 210 is placed on top of the conductor 208. In this bottom emission embodiment, the top conductor 208 may also serve as a reflector thereby eliminating the need for an independent reflector 210.

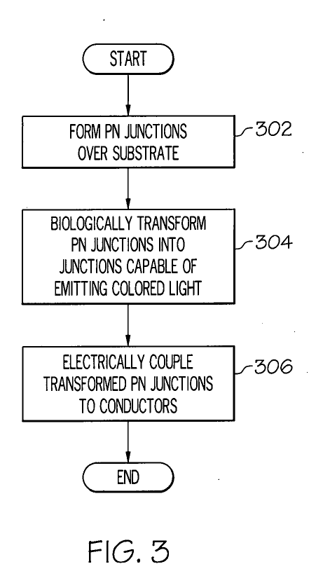

Turning now to FIG. 3, an exemplary method 300 for constructing the multi-colored ILED display 100 is illustrated. First, the backplane electronics layer 201 is formed over the substrate 202, step 302. Then, pn junctions 204 are biologically formed over the backplane electronics layer 201, step 304. The pn junctions 204 are then electrically coupled to conductors 206, 208, and thus to the backplane electronics layer 201 and the display drive electronics 112, step 306.

As briefly mentioned above, the backplane electronics layer 201 is formed over the substrate 202, step 302. It will be appreciated that the backplane electronics layer 201 may be formed using any one of numerous conventional techniques. Preferably, a technique suitable for forming a thin film transistor from materials, such as, for example, amorphous silicon, polysilicon, and organic semiconductor materials, is employed. In one exemplary embodiment, the backplane electronics layer 201 is formed with one of the conductors 206 disposed thereover. In another exemplary embodiment, the backplane electronics layer 201 is formed with a reflector 210 thereon. In still another embodiment, reflective material is disposed over the bottom conductor 206.

Next, the pn junctions 204 are biologically, formed over the backplane electronics layer 201, step 304. First, the pn junction 204 materials and biological materials for forming the pn junctions 204 are selected. Preferably, the pn junction 204 materials are selected for their capability to emit a colored light when energy is applied thereto, and the biological materials are selected from any one of numerous biological materials having a surface that has a binding specificity for a particular element or compound and that can be manipulated at relatively low temperatures. The selections of these materials may be mutually dependent on each other. In particular, the pn junction 204 materials are selected not only for suitably constructing the pn junctions 204, but also for including the element or compound for which one of the selected biological materials has an affinity.

For example, in the production of the multi-colored ILED display 100, at least three different types of semiconductor materials are used for forming the pn junctions 204 and at least three different corresponding biological materials, such as three different proteins, are selected. In one example, a first pn junction is formed using a gallium nitride-based semiconductor, a second pn junction is formed as a gallium arsenide-based semiconductor, and a third pn junction is formed as a gallium aluminum phosphide-based semiconductor. Accordingly, a first protein having an affinity for gallium nitride is selected, a second protein having an affinity for gallium arsenide is selected, and a third protein having an affinity for gallium aluminum phosphide is selected.

After the materials are selected, one of the biological materials is deposited over the substrate 202, or alternatively, over the backplane electronics layer 201 or the conductor 206, in a predetermined pattern and is contacted with a source of its corresponding pn junction 204 material. In an exemplary embodiment in which three pn junction materials have been selected and the deposition pattern of the material is similar to the particular pattern of the first, second, and third areas 102, 104, 106 of the display 100 shown in FIG. 1, pn junctions 204 are first formed over the first areas 102, and the second and third areas 104, 106 are masked. The areas 104, 106 may be masked using any one of numerous conventional masking techniques that may be performed below about 300° C.

Then, a first biological material having an affinity for a first pn junction material, is deposited in the first areas 102. The biological material may be any one of numerous biological materials having a surface that has a binding specificity for a particular element or compound and that can be manipulated at relatively low temperatures. In one exemplary embodiment, the biological material is a protein. It will be appreciated that the protein may be encapsulated in any one of numerous packages, such as as a bacteriophage, or other virus or bacteria, influencing the surface thereof to bind to a specific element or compound. The biological material may be obtained off the shelf, or may be specifically engineered. The first areas 102 may be sprayed, dipped, or otherwise contacted with the biological materials.

Next, the first biological material is contacted with its corresponding pn junction 204 material. In one exemplary embodiment, p-doped pn junction 204 material is first used; however, it will be appreciated that n-doped material may alternatively be used. The corresponding pn junction 204 material is suspended in a solution or a plasma, and is contacted with the first biological material in any one of numerous manners. For example, the pn junction 204 material may be sprayed on the areas 102, or alternatively, the substrate 202 may be bathed or dipped into containers containing a solution having the pn junction 204 material suspended therein. In any event, the solution or plasma preferably contacts the areas 102 for an amount of time that sufficiently allows the pn junction 204 material to bind to the first biological material to thereby form the first doped area 212.

After a sufficient amount of pn junction 204 material is grown in the first areas 102, first area 102 deposition of the first biological material is repeated and additional corresponding pn junction 204 material is contacted with the first biological material. In one exemplary embodiment, n-doped pn junction 204 material is contacted with the first biological material until a sufficient amount is deposited on the substrate 202 to form the second doped area 214. It will be appreciated that if n-doped material is employed in the previous step, p-doped material is preferably used in this step.

The second and third areas 104, 106 are then unmasked using any conventional technique and the process is repeated for the formation of the pn junctions 204 in the second and third areas 104, 106. For example, after the pn junctions 204 are formed in the first areas 102, the first and third areas 102, 106 are masked and the second area 104 is exposed to a second biological material and its corresponding pn junction 204 material. Then, at least the third area 106 is then unmasked, while the first and second areas 102, 104 are masked. The third area 106 is then exposed to a third biological material and its corresponding pn junction 204 material. In any event, each step in the formation of the pn junctions 204 preferably occurs in a temperature range that does not adversely affect the structural integrity of the substrate 202 material. For example, in an embodiment in which the substrate 202 is glass, the temperature range preferably does not exceed about 300° C. If the substrate 202 comprises a plastic substrate such as heat stabilized PEN (PolyEthylene Naphthalate), the temperature range preferably does not exceed about 180° C.

After the pn junctions 204 are sufficiently formed over the areas 102, 104, 106, the biological materials are removed therefrom. It will be appreciated that the removal step may occur several times throughout the contact process, or may occur once. For example, in processes in which several pn junction 204 materials and/or masking are used, the biological materials may be removed after each solution is appropriately contacted to the substrate 202. Alternatively, the biological materials may be removed at the end of the entire pn junction 204 formation process. Removal may be achieved using any one of numerous conventional thermal or chemical techniques.

Next, the top conductor 208 is formed and electrically coupled to the pn junctions 204, step 306. The top conductor 208 is common to all the pn junctions in the ILED. It will be appreciated that the conductor 208 may be formed using any one of numerous conventional techniques including conventional masking, deposition, and etching processes. The conductor 208 and the backplane layer 201 are then coupled to the display drive electronics 112 or other suitable power source.

Thus, when current is supplied by the power source to the conductors 206, 208 thereby supplying a energy to the pn junctions 204, each area 102, 104, 106 of the display 100 will emit a light having a color corresponding to the semiconductor material used in fabricating the pn junction 204 material disposed therein. Multiple colors may be created by manipulating the supply of voltage or current to one or more of the areas 102, 104, 106, and/or one or more of the diodes 200 disposed in the areas 102, 104, 106.

There has now been provided a process for manufacturing an ILED display that is relatively simple and capable of being performed in temperatures below about 300° C. In addition, the process uses a single substrate and yields high quality multi-colored ILED displays thereon.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention. It being understood that various changes may be made in the function and arrangement of elements described in an exemplary embodiment without departing from the scope of the invention as set forth in the appended claims.

What is claimed is:

1. A method of manufacturing an integrated light emitting diode display, comprising the steps of:
biologically forming a pn junction over a substrate, the pn junction capable of emitting a light having a predetermined color upon the application of energy thereto.

2. The method of claim 1, wherein the step of biologically forming comprises the steps of:
depositing a biological material over the substrate, the biological material having an affinity for a pn junction material; and
exposing the deposited biological material to the first pn junction material to form a first doped area of the pn junction.

3. The method of claim 2, wherein the step of exposing comprises exposing the deposited biological material to a p-doped or n-doped first pn junction material and the method further comprises:
depositing the biological material over the first doped area; and
exposing the biological material to the other of the p-doped or n-doped first pn junction material to form the second doped area.

4. The method of claim 1, wherein the step of biologically forming comprises creating a plurality of pn junctions over the substrate.

5. The method of claim 4, wherein the step of creating comprises:
biologically forming a first plurality of pn junctions over first areas on the substrate from a first pn junction material, the first plurality of pn junctions capable of emitting light having a first color upon application of energy thereto;
biologically forming a second plurality of pn junctions over second areas of the substrate from a second pn junction material, the second plurality of pn junctions capable of emitting light having a second color upon application of energy thereto; and
biologically forming a third plurality of pn junctions over third areas of the substrate from a third pn junction material, the third plurality of pn junctions capable of emitting light having a third color upon application of energy thereto.

6. The method of claim 5, wherein the first, second, and third colors comprise colors selected from the group consisting of red, green, and blue.

7. The method of claim 5, wherein:
the step of biologically forming a first plurality of pn junctions comprises:
depositing a first biological material over the first areas of the substrate, the first biological material having an affinity for the first pn junction material;
exposing the deposited biological material to the first pn junction material to form the first plurality of pn junctions;
the step of biologically forming a second plurality of pn junctions comprises:
depositing a second biological material over the second areas of the substrate, the second biological material having an affinity for the second pn junction material;
exposing the deposited second biological material to the second pn junction material to form the second plurality of pn junctions; and
the step of biologically forming a third plurality of pn junctions comprises:
depositing a third biological material over the third areas of the substrate, the third biological material having an affinity for the third pn junction material; and
exposing the deposited third biological material to the third pn junction material to form the third plurality of pn junctions.

8. The method of claim 7, further comprising the steps of:
masking the second and the third areas before the step of depositing the first biological material over the first areas;
unmasking the second area and masking the first and third areas before the step of depositing the second biological material over the second areas; and
unmasking the third area and masking the first and the second areas before the step of depositing the third biological material over the third areas.

9. The method of claim 7, wherein the biological material comprises a protein.

10. The method of claim 7, wherein the biological material comprises a bacteriophage having a protein encapsulated therein.

11. The method of claim 1, wherein the substrate comprises glass.

12. The method of claim 1, wherein the substrate comprises a flexible polymeric material.

13. The method of claim 1, further comprising forming a backplane electronics layer over the substrate before the step of biologically forming a pn junction.

14. The method of claim 13, wherein the backplane electronics layer comprises a material selected from the group consisting of amorphous silicon, polysilicon, and organic semiconductor.

15. The method of claim 1, wherein the pn junction comprises pn junction material having light emitting and electromagnetic radiation sensing properties.

16. A method of manufacturing a light emitting diode, comprising the steps of:
depositing a biological material over the substrate, the biological material having an affinity for a pn junction material; and
exposing the deposited biological material to the pn junction material to form a first doped area of a pn junction capable of emitting a light having a predetermined color upon the application of energy thereto.

17. A light emitting diode, comprising:
a substrate;
a biologically formed pn junction disposed over the substrate, wherein light having a predetermined color is emitted upon application of energy to the pn junction.

18. The light emitting diode of claim 17, wherein the substrate comprises glass.

19. The light emitting diode of claim 17, further comprising conductors disposed over the substrate and electrically coupled to the pn junction.

20. The light emitting diode of claim 19, further comprising a reflector layer disposed over the substrate and under the first and second conductors.

21. The light emitting diode of claim 17, further comprising a first, a second, and a third pn junction formed over the substrate, each pn junction capable of emitting a first, second, and third color, respectively, upon application of energy thereto.

22. The light emitting diode of claim 17, further comprising a backplane electronic thin film transistor disposed between the substrate and the pn junction.

23. The light emitting diode of claim 22, wherein the backplane electronic thin film transistor comprises material selected from the group consisting of amorphous silicon, polysilicon, and organic semiconductor.
